(19) United States
(12) Patent Application Publication
(10) Pub. No.: US 2021/0342678 A1
(43) Pub. Date: Nov. 4, 2021

(54) COMPUTE-IN-MEMORY ARCHITECTURE FOR NEURAL NETWORKS

(71) Applicant: THE REGENTS OF THE UNIVERSITY OF CALIFORNIA, Oakland, CA (US)

(72) Inventors: Hesham Mostafa, San Diego, CA (US); Rajkumar Chinnakonda Kubendran, San Diego, CA (US); Gert Cauwenberghs, San Diego, CA (US)

(21) Appl. No.: 17/261,462

(22) PCT Filed: Jul. 19, 2019
(86) PCT No.: PCT/US2019/042690

§ 371 Date: Jan. 19, 2021

Related U.S. Application Data
(60) Provisional application No. 62/700,782, filed on Jul. 19, 2018.

(51) Int. Cl. G06N 3/063; H01L 27/24; G06N 3/08

(52) U.S. Cl. CPC G06N 3/063; G06N 3/084; H01L 27/2463

(57) ABSTRACT

A compute-in-memory neural network architecture combines neural circuits implemented in CMOS technology and synaptic conductance crossbar arrays. The crossbar memory structures store the weight parameters of the neural network in the conductances of the synapse elements, which define interconnects between lines of neurons of consecutive layers in the network at the crossbar intersection points.

### RELATED APPLICATIONS

This application claims the benefit of the priority of U.S. Provisional Application No. 62/700,782, filed Jul. 19, 2018, which is incorporated herein by reference.

### FIELD OF THE INVENTION

The present invention relates to a CMOS-based architecture for implementing a neural network with accelerated learning.

### BACKGROUND OF THE INVENTION

Biological neural networks process information in a qualitatively different manner from conventional digital processors. Unlike the sequence of instructions programing model employed by conventional von Neumann architectures, the knowledge, or the program in a neural network is largely encoded in the pattern and strength/weight of the synaptic connections. This programming model is key to the adaptability and resilience of neural networks, which can continuously learn by adjusting the weights of the synaptic connections.

Multi-layer neural networks are extremely powerful function approximators that can learn complex input-output relations. Backpropagation is the standard training technique that adjusts the network parameters or weights to minimize a particular objective function. This objective function is chosen so that it is minimized when the network exhibits the desired behavior. The overwhelming majority of compute devices used in the training phase and in the deployment phase of neural networks are digital devices. However, the fundamental compute operation used during training and inference is the multiply and accumulate (MAC) operation, which can be efficiently and cheaply realized in the analog domain. In particular, the accumulate operation can be implemented at zero silicon cost by representing the summands as currents and adding them at a common node. Besides computation, a central efficiency bottleneck when training and deploying neural networks is the large volume of memory traffic to fetch and write back the weights to memory.

Novel nonvolatile memory technologies like resistive random-access memories (RRAM), phase change memories (PCM), and magnetoresistive random-access memories (MRAM) have been described in the context of dense digital storage and read/write power efficiency. These types of memories store information in the conductance states of nano-scale elements. This enables a unique form of analog in-memory computing where voltages applied across networks of such nano-scale elements result in currents and internal voltages that are arithmetic functions of the applied voltages and the conductances of the elements. By storing the weights of the neural network as conductance values of the memory elements, and by arranging these elements in a crossbar configuration as shown in FIG. 1, the crossbar memory structure can be used to perform a matrix-vector product operation in the analog domain. In the illustrated example, the input layer 10 neural activity, y^{l-1}, is encoded as analog voltages. The output neurons 12 maintain a virtual ground at their input terminals and their input currents represent weighted sums of the activities of the neurons in the previous layer, where the weights are encoded in the memory-resistor, or “memristor”, conductances 14a-14n. The output neurons generate an output voltage proportional to their input currents. Additional details are provided by S. Hamdioui, et al., in “Memristor For Computing: Myth of Reality?”, Proceedings of the Conference on Design, Automation & Test in Europe (DATE), IEEE, pp. 722-731, 2017. This approach has two advantages: (1) weights do not need to be shuttled between memory and a compute device as computation is done directly within the memory structure; and (2) minimal computing hardware is needed around the crossbar array as most of the computation is done through Kirchoff's current and voltage laws. A common issue with this type of memory structure is a data-dependent problem called “sneak paths”. This phenomenon occurs when a resistor in the high-resistance state is being read while a series of resistors in the low-resistance state exist parallel to it, causing it to be erroneously read as low-resistance. The “sneak path” problem in analog crossbar array architectures can be avoided by driving all input lines with voltages from the input neurons. Other approaches involve including diodes or transistors to isolate each device, which limits array density and increases cost.

Deep neural networks have demonstrated state-of-the-art performance on a variety of tasks such as image classification and automatic speech recognition. Before neural networks can be deployed, however, they must first be trained. The training phase for deep neural networks can be very power-hungry and is typically executed on centralized and powerful computing systems. The network is subsequently deployed and operated in the “inference mode” where the network becomes static and its parameters fixed. This use scenario is dictated by the prohibitively high power costs of the “learning mode” which makes it impractical for use on power-constrained deployment devices such as mobile phones or drones. This use scenario, in which the network does not change after deployment, is inadequate in situations where the network needs to adapt online to new stimuli, or to personalize its output to the characteristics of different environments or users.

### BRIEF SUMMARY

While the use of crossbar memory structures for implementing the inference phase in neural networks has been previously disclosed, the inventive approach provides a complete network architecture for carrying out both learning and inference in a novel fashion based on binary neural networks and approximate backpropagation learning.

According to embodiments of the invention, an efficient compute-in-memory architecture is provided for on-line deep learning by implementing a combination of neural circuits in complementary metal-oxide semiconductor (CMOS) technology, and synaptic conductance crossbar arrays in resistive nonvolatile random-access memory (RRAM) technology+. The crossbar memory structures store the weight parameters of the deep neural network in the conductances of the RRAM synapse elements, which make interconnects between lines of neurons of consecutive layers in the network at the crossbar intersection points. The architecture makes use of binary neurons. It uses the conductance-based representation of the network weights in order to execute multiply and accumulate (MAC) operations in the analog domain. The architecture uses binary neuron activations, and also uses an approximate version of the backpropagation learning technique to train the RRAM synapse weights with trinary truncated updates during the error backpropagation pass.

Disclosed are design and implementation details for the inventive CMOS device with integrated crossbar memory structures for implementing multi-layer neural networks. The inventive device is capable of running both the inference steps and the learning steps. The learning steps are based on a computationally efficient approximation of standard backpropagation.

According to an exemplary embodiment, the inventive architecture is based on Complementary Metal Oxide Semiconductor (CMOS) technology and crossbar memory structures in order to accelerate both the inference mode and the learning mode of neural networks. The crossbar memory structures store the network parameters in the conductances of the elements at the crossbar intersection points (the points at the intersection of a horizontal metal line and a vertical metal line). The architecture makes use of binary neurons. It uses the conductance-based representation of the network weights in order to execute multiply and accumulate (MAC) operations in the analog domain. With binary outputs, it is not necessary to acquire output current by clamping the voltage to zero (virtual ground) on the output lines, and it is sufficient to compare voltage directly against a zero threshold, which is easily accomplished using a standard voltage comparator, such as a CMOS dynamic comparator, on the output lines. With binary inputs driving the input lines, the “sneak path” problem in the analog crossbar array is entirely avoided. The architecture uses an approximate version of the backpropagation learning technique to train the weights in the “weight memory structures” in order to minimize a cost function. During the backward pass, the approximate backpropagation learning uses ternary errors and a hardware-friendly approximation of the gradient of the binary neurons.

The inventive approach represents the first truly integrated RRAM-CMOS realization that supports fully autonomous on-line deep learning. The ternary truncated error backpropagation architecture offers a hardware-friendly approximation of the true gradient of the error in the binary neurons. Through the use of binary neurons, ternary errors, approximate gradients, and analog-domain MACs, the developed device achieves compact and power-efficient learning and inference in multi-layer networks.

In one aspect of the invention, a neural network architecture for inference and learning includes a plurality of network modules, each network module comprising a combination of CMOS neural circuits and RRAM synaptic crossbar memory structures interconnected by bit lines and source lines, each network module having an input port and an output port, wherein weights are stored in the crossbar memory structures, and wherein learning is effected using approximate backpropagation with ternary errors. The CMOS neural circuits include a source line block having dynamic comparators, so that inference is effected by clamping pairs of bit lines in a differential manner and comparing within the dynamic comparator voltages on each differential bit line pair to obtain a binary output activation for output neurons. The comparison may be performed in parallel across all source line pairs. In a preferred embodiment, the use of binary outputs obviates the need for virtual ground nodes.

The architecture may further include a plurality of switches disposed within the bit lines and source lines between adjacent network modules, so that closing a switch in bit lines between adjacent network modules creates a layer with additional input neurons and closing a switch in source lines between adjacent network modules creates a layer with additional output neurons. A plurality of routing switches may be configured to connect input ports and output ports of the network modules to flow binary activations forward and binary errors backward.

In another aspect of the invention, a neural network architecture configured for inference and learning includes a plurality of network modules arranged in an array, where each network module is configured to implement lines and one or more layers of binary neurons via a combination of CMOS neural circuits and a conductance crossbar array configured to store synapse elements weights, wherein crossbar intersections within the crossbar array define interconnects between lines of neurons of consecutive layers in the network structure, and wherein the synapse element weights are trained using backpropagation with trinary truncated updates. The crossbar intersections correspond to intersections between bit lines and source lines, and the CMOS neural circuits include a source line block having dynamic comparators, so that inference can be effected by clamping pairs of bit lines in a differential manner and comparing within the dynamic comparator voltages on each differential bit line pair to obtain a binary output activation for output neurons. The comparison can be performed in parallel across all source line pairs. The use of binary outputs allows sneak paths to be avoided without relying on virtual ground nodes. A plurality of switches may be disposed within the bit lines and source lines between adjacent network modules so that closing a switch in bit lines between adjacent network modules creates a layer with additional input neurons and closing a switch in source lines between adjacent network modules creates a layer with additional output neurons. A plurality of routing switches may be provided to connect input ports and output ports of the network modules to flow binary activations forward and binary errors backward.

In still another aspect of the invention, a compute-in-memory CMOS architecture includes a combination of neural circuits implemented in complementary metal-oxide semiconductor (CMOS) technology and synaptic conductance crossbar memory structures implemented in resistive nonvolatile random-access memory (RRAM) technology. The crossbar memory structures store weight parameters of a neural network in the conductances of synapse elements at crossbar intersection points, wherein the crossbar intersection points correspond to interconnects between lines of neurons of consecutive layers in the network. The crossbar intersection points correspond to intersections between bit lines and source lines, and the CMOS neural circuits include a source line block having dynamic comparators, so that inference can be effected by clamping pairs of bit lines in a differential manner and comparing within the dynamic comparator voltages on each differential bit line pair to obtain a binary output activation for output neurons. The comparison can be performed in parallel across all source line pairs. The use of binary outputs allows sneak paths to be avoided without relying on virtual ground nodes.

The architecture can be used to form an array of network modules, where each module includes the combination of neural circuits implemented in CMOS technology and synaptic conductance crossbar memory structure implemented in RRAM technology, and a plurality of switches is disposed within the bit lines and source lines between adjacent network modules so that closing a switch in bit lines between adjacent network modules creates a layer with additional input neurons and closing a switch in source lines between adjacent network modules creates a layer with additional output neurons. A plurality of routing switches may be configured to connect input ports and output ports of the network modules to flow binary activations forward and binary errors backward.

The inventive architecture is applicable to virtually all domains of industrial activity and product development that are now heavily investing in deep learning and artificial intelligence (DL/AI) technology to automate the range of functionalities offered to the customer. Self-learning microchips fill an important gap between the bulky, power-hungry computer hardware of central/graphical processor unit (CPU/GPU) clusters running DL/AI algorithms running in the cloud, and the need for ultra-low power for internet-of-things (IoT) running on the edge.

### BRIEF DESCRIPTION OF THE DRAWINGS

FIG. 1 illustrates a general form of a conductance-based ANN implementation of a single feedforward layer as disclosed in the prior art.

FIG. is a block diagram of a basic building blocks for a network module (NM) according to an embodiment of the invention.

FIG. 3 illustrates an array of network modules according to an embodiment of the invention connected by routing switches for routing binary activations and binary errors between the NMs.

FIG. 4 shows an exemplary waveform used to clamp the bit lines during the inference (forward pass) where neuron x₁ activation is +1 and neuron x₂ activation is −1. The input to the neurons in the next layer can be obtained from the voltages on the source lines. A dotted line indicates a floating (high impedance state).

FIG. 5 illustrates the waveforms used during the backward pass to clamp the SLs using ternary errors. The errors at the input neurons x₁ and x₂ can be obtained from the voltages on the source lines. A dotted line indicates a floating (high impedance state).

FIGS. 6A and 6B each depict the waveforms used during the weight update phase where voltages are applied across the memory elements to update the weights based on the errors at the output neurons (y₁ and y₂) and the activity of the input neurons (x₁ and x₂). A dotted line indicates a floating (high impedance state).

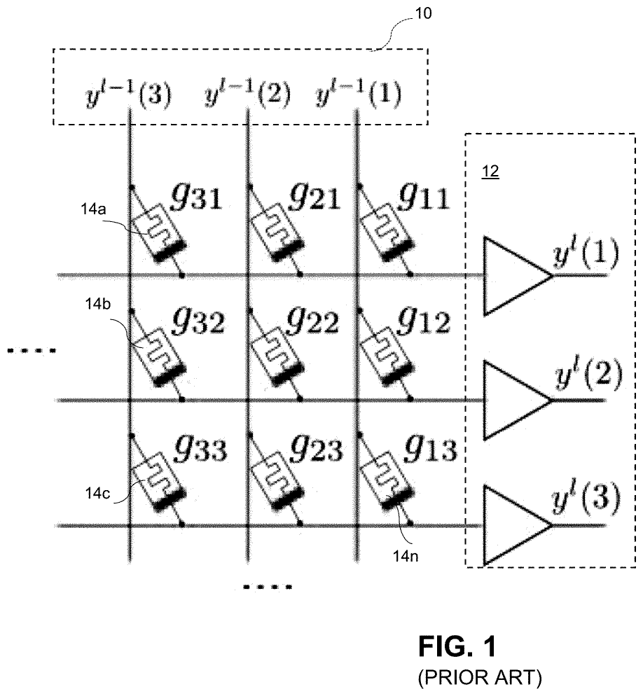

### DETAILED DESCRIPTION OF EMBODIMENTS OF THE INVENTION

According to an embodiment of the inventive architecture, an array of network modules is assembled using CMOS technology. The array is an N×M array of conductance-based memory elements 18 arranged in a crossbar configuration and connected through switches. FIG. 2 depicts an exemplary network module 20 with a 4×4 implementation. This example is provided for illustration purposed only and is not intended to be limiting—N and M can be any integers. The vertical lines in the crossbar are called the source lines (SL) 22 and the horizontal lines are the bit lines (BL) 24. Binary errors and activations are communicated in a bit-serial fashion through the bi-directional HL 26 and VL 28 lines.

The network module (NM) 20 implements a whole layer or part of a layer of a neural network with N/2 input neurons and M/2 output neurons (2 input neurons (x₁, x₂) and 2 output neurons y₁, y₂) are included in the example shown in FIG. 2.) Four memory elements 18 are used to represent each connection weight from input neuron to output neuron. CMOS circuits on the periphery of the crossbar memory structure control the forward pass, where the BLs 24 are clamped by the BL block 27 and voltages are measured on the SLs 22 by the SL block 29, and the backward pass, where the SLs are clamped by the SL block 29 and voltages are measured on the BLs by the BL block. In the weight update, the BLs 24 and the SLs 22 are clamped in order to update the conductances of the memory elements representing the weights.

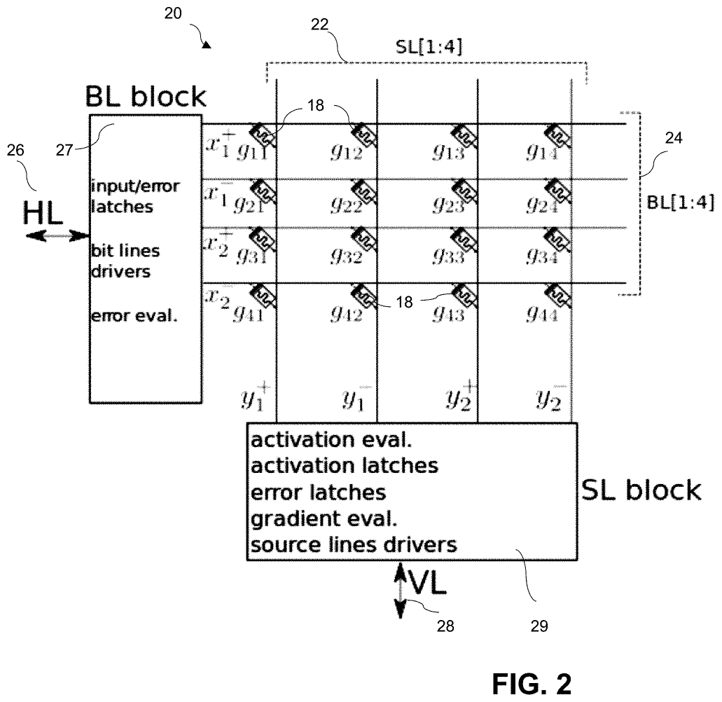

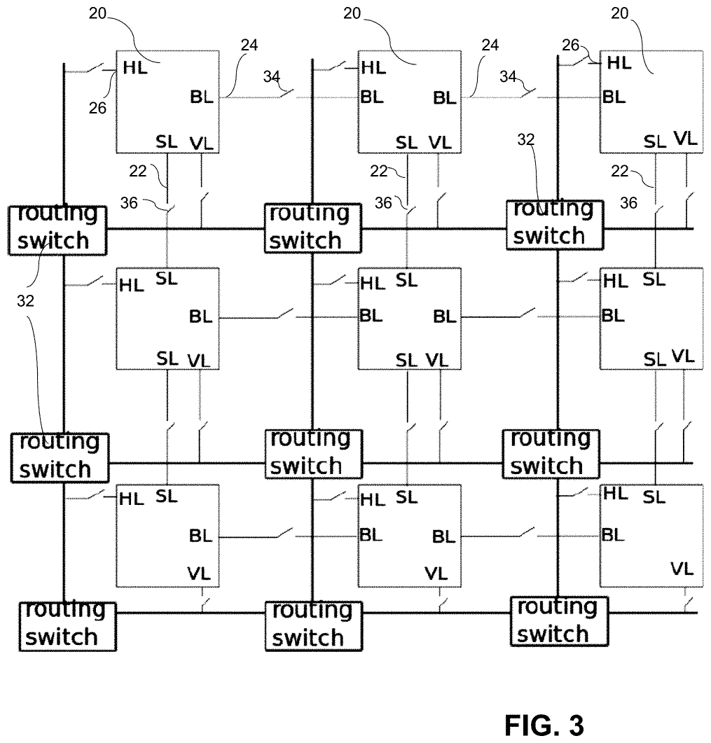

FIG. 3 diagrammatically illustrates an array of NMs 20 to define an exemplary neural network architecture, in this case with nine modules. The number of modules illustrated in the figure is provided as an example only and is not intended to be limiting. Each NM 20 exposes its BLs 24 and SLs 22 on the periphery. By closing transmission gate switches 34 and 36, respectively, the BLs 24 and SLs 22 of each NM 20 can be shorted to the corresponding line of neighboring modules to realize layers with more than N/2 input or M/2 output neurons. Routing switches 32 connect the bit-serial digital input/output ports of the modules 20 to allow binary activations to flow forward in the network and binary errors to flow backwards (errors are communicated in binary fashion and ternarized at the SL blocks as described below). The routing switches 32 are 4-way switches that can short together (through transmission gates) any of the input/output lines (left, right, top, or bottom) to any other input/output line.

Forward pass (inference): Referring still to FIG. 3, an NM 20 implements binary neurons where the activation value of each neuron is a 2-valued quantity. The NM 20 receives the binary activations from the previous layer in a bit-serial manner through the HL line 26. These activations are stored in latches in BL block 27. Once the activations for the input neurons in the NM have been received, the NM clamps the BLs 24 in a differential manner as shown in FIG. 2. Shortly after the BLs have been clamped, dynamic comparators in the SL block 29 compare the voltages on each differential input pair to obtain the binary output activations for neurons y₁ and y₂. If the plus (+) line is higher than the minus (−) line, the activation is +1 (binary 1), otherwise the activation is −1 (binary 0). The comparison is done in parallel across all the SL pairs. The BLs 24 are then left floating again. The binary activations of y₁ and y₂ are stored in latches and streamed in a bit-serial fashion through VL 28 where they form the input to the next NM.

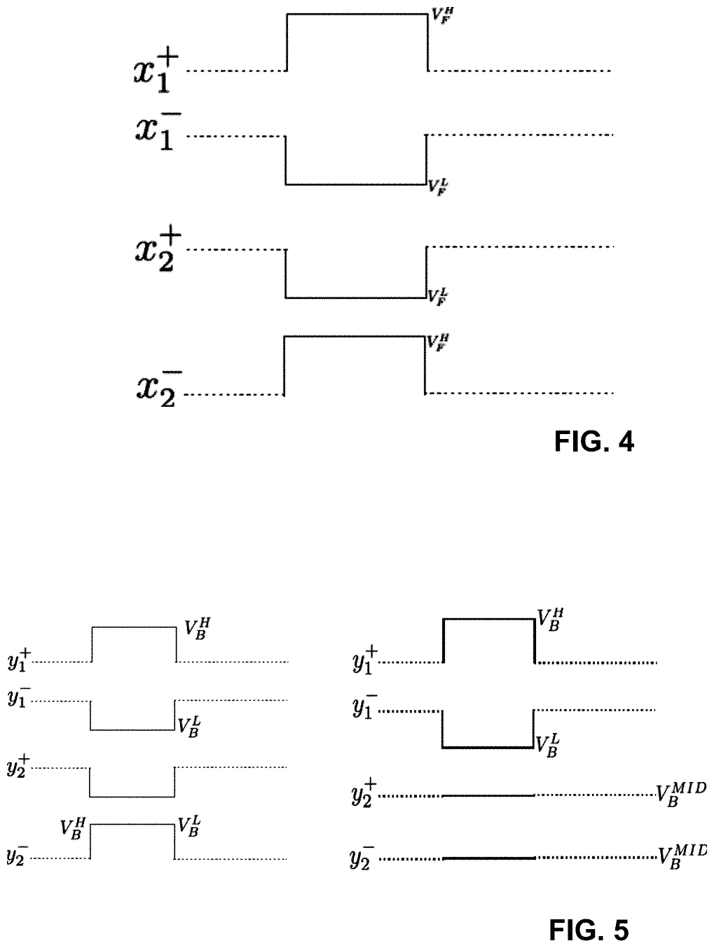

FIG. 4 shows an exemplary waveform used to clamp the bit lines during the inference (forward pass) where neuron x₁ activation is +1 and neuron x₂ activation is −1. The input to the neurons in the next layer can be obtained from the voltages on the source lines. A dotted line indicates a floating (high impedance state).

Backward pass: The NMs 20 collectively implement an approximate version of backpropagation learning where errors from the top layer are backpropagated down the stack of layers and used to update the weights of the memory elements. The approximation has two components: approximating the back-propagating errors by a ternary value (−1, 0, or 1), and approximating the zero gradient of the neuron's binary activation function by a non-zero value that depends on the neuron's activation and the error arriving at the neuron. FIG. 5 illustrates the waveforms used during the backward pass to clamp the SLs using ternary errors. The errors at the input neurons x₁ and x₂ can be obtained from the voltages on the source lines. A dotted line indicates a floating (high impedance state). The backward pass proceeds as follows through a NM:

1) The NM 20 receives binary errors (−1, +1) in a bit-serial fashion through the VL line 28. The binary errors are stored in latches in the SL block 29.

2) The NM 20 carries out an XOR operation between a neuron's activation bit and the error bit to obtain the update bit. If the update bit is 0, this means the activation and the error have the same sign and changing the neuron's activation is not required to reduce the error. Otherwise, if the update bit is 1, the error bit has a different sign than the activation and the neuron's output need to change to reduce the error. The ternary error is obtained from the update bit and the binary error bit: if the update bit is 0, the ternary error is 0, otherwise the ternary error is +1 if the binary error is +1 and −1 if the binary error is −1.

3) The ternary error calculated from the previous step at each output neuron (for example y₁, y₂) are used to clamp the differential source lines corresponding to each neuron as shown in FIG. 5. When the ternary error is 0, the two corresponding SLs are clamped at a mid-voltage. When it is +1, or −1, the SL pairs are clamped in a complementary fashion. Shortly after the SLs have been clamped, dynamic comparators in the BL block compare the voltages on each differential BL pair to obtain the binary errors at input neurons x₁ and x₂. The error is +1 (binary 1) if the plus (+) line is higher than the minus (−) line on a BL pair, and −1 (binary 0) otherwise. The comparison is done in parallel across all the BL pairs. The SLs are then left floating again. The binary errors at x₁ and x₂ are stored in latches and streamed in a bit-serial fashion through HL where they form the binary errors at the previous NM.

4) In the forward step and all the previous steps in the backward pass, the applied voltages are small enough to avoid perturbing the conductances of the memory elements 18, i.e., avoid perturbing the weights. In this step, we apply voltages simultaneously on the BLs 24 and the SLs 22 so as to update the conductance elements' values based on the activations of the input neurons (x₁ and x₂) and the ternary errors at the output neurons (y₁ and y₂).

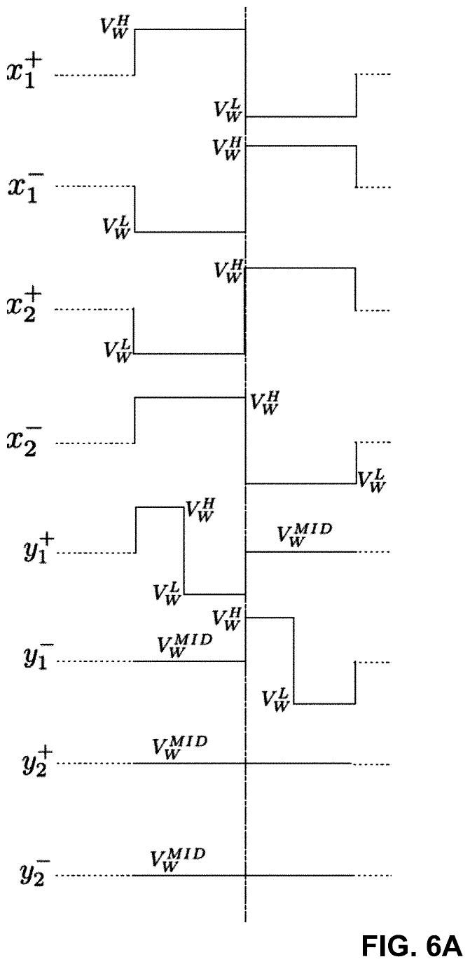

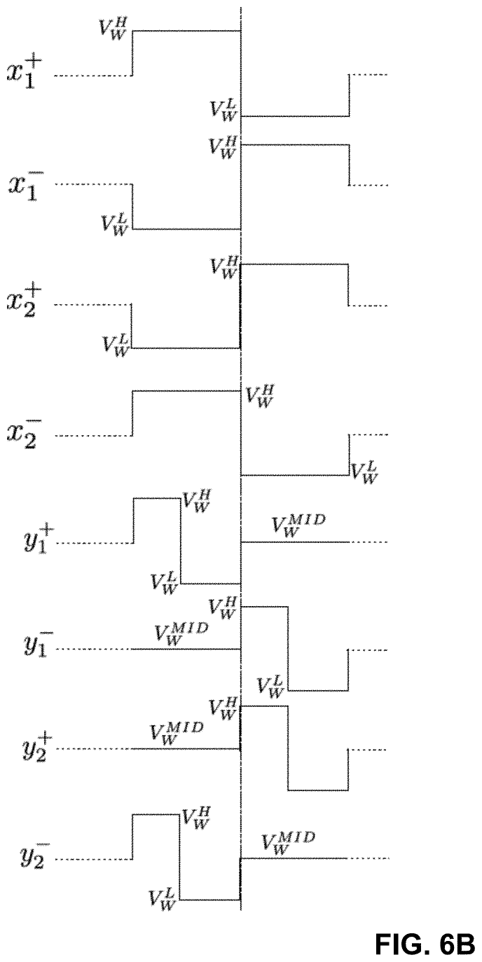

FIGS. 6A and 6B illustrate the waveforms used for all possible binary activation values (+1 or −1) and for all possible ternary error values (+1, −1, and 0). We assume the memory elements have bipolar switching characteristics with a threshold: A positive voltage with magnitude above threshold (where the BLs are taken as the positive terminals) applied across the memory elements increases their conductance and a negative voltage with absolute value above threshold decreases their conductance. The write waveforms depicted in FIGS. 6A and 6B are designed in such a way so as to increase the effective weight between a pair of neurons (represented by 4 memory elements) when the product of the input neuron's activation and the output neuron's error is positive, decrease the weight when the product is negative, and leave the weight unchanged when the product is zero (which happens only when the ternary error is zero). The voltage levels are chosen such that the applied voltage across a memory element (difference between the voltage of its BL and the voltage of its SL) is above threshold only if one of the voltages is high (with an ‘H’ in the superscript) and the other is low (with an ‘L’ in the superscript).

The CMOS architecture neural network disclosed herein provides for inference and learning using weights stored in crossbar memory structures, where learning is achieved using approximate backpropagation with ternary errors. The inventive approach provides an efficient inference stage, where dynamic comparators are used to compare voltages across differential wire pairs. The use of binary outputs allows sneak paths to be avoided without having to rely on clamping to virtual ground.

The inventive approach represents the first truly integrated RRAM-CMOS realization that supports fully autonomous on-line deep learning. The ternary truncated error backpropagation architecture offers a hardware-friendly approximation of the true gradient of the error in the binary neurons. Through the use of binary neurons, ternary errors, approximate gradients, and analog-domain MACs, the developed device achieves compact and power-efficient learning and inference in multi-layer networks.

The inventive architecture is applicable to virtually all domains of industrial activity and product development that are now heavily investing in deep learning and artificial intelligence (DL/AI) technology to automate the range of functionalities offered to the customer. Self-learning microchips fill an important gap between the bulky, power-hungry computer hardware of central/graphical processor unit (CPU/GPU) clusters running DL/AI algorithms running in the cloud, and the need for ultra-low power for internet-of-things (IoT) running on the edge.

1. A neural network architecture for inference and learning comprising:
a plurality of network modules, each network module comprising a combination of CMOS neural circuits and RRAM synaptic crossbar memory structures interconnected by bit lines and source lines, each network module having an input port and an output port, wherein weights are stored in the crossbar memory structures, and wherein learning is effected using approximate backpropagation with ternary errors.

2. The architecture of claim 1, wherein the CMOS neural circuits include a source line block having dynamic comparators, and wherein inference is effected by clamping pairs of bit lines in a differential manner and comparing within the dynamic comparator voltages on each differential bit line pair to obtain a binary output activation for output neurons.

3. The architecture of claim 2, wherein the comparison is performed in parallel across all source line pairs.

4. The architecture of claim 1, wherein pairs of bit lines are clamped in a differential manner so that a binary output activation is generated at the output port.

5. The architecture of claim 1, further comprising a plurality of switches disposed within the bit lines and source lines between adjacent network modules, wherein closing a switch in bit lines between adjacent network modules creates a layer with additional input neurons and closing a switch in source lines between adjacent network modules creates a layer with additional output neurons.

6. The architecture of claim 1, further comprising a plurality of routing switches configured to connect input ports and output ports of the network modules to flow binary activations forward and binary errors backward.

7. A neural network architecture configured for inference and learning, the architecture comprising:
a plurality of network modules arranged in an array, each network module configured to implement lines and one or more layers of binary neurons via a combination of CMOS neural circuits and a conductance crossbar array configured to store synapse elements weights, wherein crossbar intersections within the crossbar array define interconnects between lines of neurons of consecutive layers in the network structure, and wherein the synapse element weights are trained using backpropagation with trinary truncated updates.

8. The architecture of claim 7, wherein the crossbar intersections comprise intersections between bit lines and source lines, and wherein the CMOS neural circuits include a source line block having dynamic comparators, and wherein inference is effected by clamping pairs of bit lines in a differential manner and comparing within the dynamic comparator voltages on each differential bit line pair to obtain a binary output activation for output neurons.

9. The architecture of claim 8, wherein the comparison is performed in parallel across all source line pairs.

10. The architecture of claim 7, wherein the crossbar intersections comprise intersections between bit lines and source lines, and wherein pairs of bit lines are clamped in a differential manner so that a binary output activation is generated at an output port.

11. The architecture of claim 7, further comprising a plurality of switches disposed within the bit lines and source lines between adjacent network modules, wherein closing a switch in bit lines between adjacent network modules creates a layer with additional input neurons and closing a switch in source lines between adjacent network modules creates a layer with additional output neurons.

12. The architecture of claim 7, further comprising a plurality of routing switches configured to connect input ports and output ports of the network modules to flow binary activations forward and binary errors backward.

13. A compute-in-memory CMOS architecture comprising a combination of neural circuits implemented in complementary metal-oxide semiconductor (CMOS) technology and synaptic conductance crossbar memory structures implemented in resistive nonvolatile random-access memory (RRAM) technology, wherein the crossbar memory structures store weight parameters of a neural network in the conductances of synapse elements at crossbar intersection points, wherein the crossbar intersection points correspond to interconnects between lines of neurons of consecutive layers in the network.

14. The architecture of claim 13, wherein the crossbar intersection points correspond to intersections between bit lines and source lines, and wherein the CMOS neural circuits include a source line block having dynamic comparators, and wherein inference is effected by clamping pairs of bit lines in a differential manner and comparing within the dynamic comparator voltages on each differential bit line pair to obtain a binary output activation for output neurons.

15. The architecture of claim 14, wherein the comparison is performed in parallel across all source line pairs.

16. The architecture of claim 13, wherein the crossbar intersection points correspond to intersections between bit lines and source lines, and wherein pairs of bit lines are clamped in a differential manner so that a binary output activation is generated at an output port.

17. The architecture of claim 13, further comprising an array of network modules, each module comprising the combination of neural circuits implemented in CMOS technology and synaptic conductance crossbar memory structure implemented in RRAM technology, and wherein a plurality of switches is disposed within the bit lines and source lines between adjacent network modules, wherein closing a switch in bit lines between adjacent network modules creates a layer with additional input neurons and closing a switch in source lines between adjacent network modules creates a layer with additional output neurons.

18. The architecture of claim 17, further comprising a plurality of routing switches configured to connect input ports and output ports of the network modules to flow binary activations forward and binary errors backward.
